(19) United States
(12) Patent Application Publication
(10) Pub. No.: US 2026/0117377 A1
(43) Pub. Date: Apr. 30, 2026

(54) MANIFOLD AND SEMICONDUCTOR WAFER PROCESSING APPARATUS INCLUDING MANIFOLD

(71) Applicant: Samsung Electronics Co., Ltd., Suwon-si (KR)

(72) Inventors: Yongkeun Kang, Suwon-si (KR); Sunguk Kim, Suwon-si (KR); Seonghyun Sin, Suwon-si (KR); Jeonghoon Shin, Suwon-si (KR); Hyomin Shim, Suwon-si (KR); Cheolsoo Yang, Suwon-si (KR); Taepyo Hong, Suwon-si (KR)

(21) Appl. No.: 19/003,627

(22) Filed: Dec. 27, 2024

(30) Foreign Application Priority Data
Mar. 4, 2024 (KR) 10-2024-0030874

(51) Int. Cl. C23C 16/455; C23C 16/44; C23C 16/505; H01J 37/32; H01L 21/683

(52) U.S. Cl. CPC C23C 16/45561; C23C 16/4405; C23C 16/45574; H01J 37/3244; H01J 37/32862; C23C 16/505; H01J 37/32082; H01J 2237/3321; H10P 72/722

(57) ABSTRACT

A manifold including a manifold body having an upper surface, a lower surface, at least one side surface between the upper surface and the lower surface, an upper hole in the upper surface, a lower hole in the lower surface, a first inlet, a second inlet, a first outlet, and a second outlet, an inclined partition separating the upper hole and the lower hole from each other in a thickness direction of a central portion of the manifold body, a first gas flow path between the upper hole above the inclined partition and the first outlet of the manifold body, a second gas flow path between the first inlet and a side surface of the lower hole below the inclined partition and continuing to the lower hole of the manifold body, and a third gas flow path between the second inlet and the second outlet of the manifold body.

### CROSS-REFERENCE TO RELATED APPLICATION(S)

This application claims benefit of priority to Korean Patent Application No. 10-2024-0030874 filed on Mar. 4, 2024, in the Korean Intellectual Property Office, the disclosure of which is incorporated herein by reference in its entirety.

### BACKGROUND

The present inventive concept relates to a manifold and a semiconductor wafer processing apparatus including the same.

Among semiconductor processes for manufacturing semiconductor devices, a deposition process or an etching process may be performed, using a semiconductor wafer processing apparatus using plasma.

Due to the nature of an amorphous carbon film deposition process for patterning new-generation NAND and DRAM devices, plasma cleaning using O₂ gas may be required. When a post-deposition cleaning process is repeatedly performed or a deposition process is performed for a long period of time, a carbon film material may be deposited in a space other than an O₂ plasma region, for example, a bottom portion or a pipe portion of a processing chamber, and the carbon particles may fall to the bottom portion, causing pipe clogging.

In addition, in an amorphous carbon film deposition process, performed at high temperature, plasma cleaning may be undertaken using O₂ gas supplied through a showerhead, such a carbon-deposited film material may be cleaned only in a plasma region for a process between the showerhead and an electrostatic chuck, and a carbon film material may accumulate in a lower portion of a processing chamber, a vacuum pipe, and a throttle valve portion, spaces other than the plasma region, causing an issue such as process stopping or pipe clogging.

### SUMMARY

An aspect of the present inventive concept provides a manifold for changing a plasma cleaning gas flow path to prevent a carbon film material from being deposited on a bottom portion of a processing chamber or a pipe portion.

Another aspect of the present inventive concept provides a semiconductor wafer processing apparatus having a bypass plasma cleaning gas flow path to directly remove a carbon film material collected on a bottom portion of a processing chamber.

According to an aspect of the present inventive concept, there is provided a manifold including a manifold body having an upper surface, a lower surface, at least one side surface between the upper surface and the lower surface, an upper hole in the upper surface, a lower hole in the lower surface, a first inlet, a second inlet, a first outlet, and a second outlet, an inclined partition separating the upper hole and the lower hole from each other in a thickness direction of a central portion of the manifold body, a first gas flow path providing fluid communication between the upper hole above the inclined partition and the first outlet of the manifold body, a second gas flow path providing fluid communication between the first inlet and a side surface of the lower hole below the inclined partition and continuing to the lower hole of the manifold body, and a third gas flow path providing fluid communication between the second inlet and the second outlet of the manifold body.

According to another aspect of the present inventive concept, there is provided a semiconductor wafer processing apparatus including a processing chamber having a chamber lid at an upper portion thereof and an internal space, a remote plasma source disposed at an upper portion of the chamber lid, the remote plasma source supplying a plasma cleaning gas to the internal space of the processing chamber, and a manifold disposed between the remote plasma source and the chamber lid, the manifold providing gas distribution flow paths to the processing chamber. The gas distribution flow paths of the manifold provide a first cleaning gas, supplied by the remote plasma source, to the internal space of the processing chamber through a sidewall of the processing chamber via the chamber lid.

According to another aspect of the present inventive concept, there is provided a semiconductor wafer processing apparatus including a processing chamber having a chamber lid at an upper portion thereof and an internal space, a manifold disposed on the chamber lid, the manifold providing gas distribution flow paths to the processing chamber, and a remote plasma source supplying a plasma cleaning gas to the internal space of the processing chamber through the manifold. The manifold may include a manifold body having an upper surface, a lower surface, at least one side surface between the upper surface and the lower surface, an upper hole in the upper surface, a lower hole in the lower surface, a first inlet, a second inlet, a first outlet, and a second outlet, an inclined partition separating an upper hole and a lower hole from each other in a thickness direction of a central portion of the manifold body, a first gas flow path communicating from the upper hole above the inclined partition to the first outlet of the manifold body, a second gas flow path communicating from the first inlet to a side surface of the lower hole below the inclined partition and continuing to the lower hole of the manifold body, and a third gas flow path communicating from the second inlet to the second outlet of the manifold body.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic cross-sectional view of a semiconductor wafer processing apparatus according to an example embodiment of the present inventive concept;

FIG. 2 is a schematic perspective view of a lower surface of a manifold according to an example embodiment of the present inventive concept;

FIG. 3 is a schematic diagram of an upper surface of the manifold of FIG. 2;

FIG. 4 is a schematic diagram of a lower surface of the manifold of FIG. 2;

FIG. 5 is a schematic diagram of a cross-section of the manifold of FIG. 2;

FIG. 6 is a schematic diagram of a bypass flow path through which a plasma cleaning gas flows in the semiconductor wafer processing apparatus of FIG. 1; and

FIG. 7 is a schematic perspective view of the processing chamber of FIG. 6.

### DETAILED DESCRIPTION

Hereinafter, example embodiments of the present inventive concept will be described with reference to the attached drawings, in which various embodiments are shown.

Example embodiments of the present inventive concept may be modified into many different forms, and may be provided for a more complete description of the present inventive concept to those skilled in the art. Accordingly, the shapes and sizes of the components in the drawings may be exaggerated for clarity of description, and components denoted by the same reference numerals in the drawings may be the same components. It should also be emphasized that the disclosure provides details of alternative examples, but such listing of alternatives is not exhaustive. Furthermore, any consistency of detail between various examples should not be interpreted as requiring such detail.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.”

In the context of fluid communication, components or spaces may be described as being in “communication” with each other are configured such that a fluid may flow from one component or space to the other. The components may be in direct communication in which the fluid may flow from one component directly to the other component without passing through another component, or they may be in indirect communication in which the fluid may pass through other components between the components when flowing from one component to the other.

As used herein, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

The terms used herein describe particular example embodiments only, and the present inventive concept is not limited thereby. As used herein, singular forms “a,” “an,” and “the” are intended to include the plural forms as well, unless the context clearly indicates otherwise.

### Semiconductor Wafer Processing Apparatus

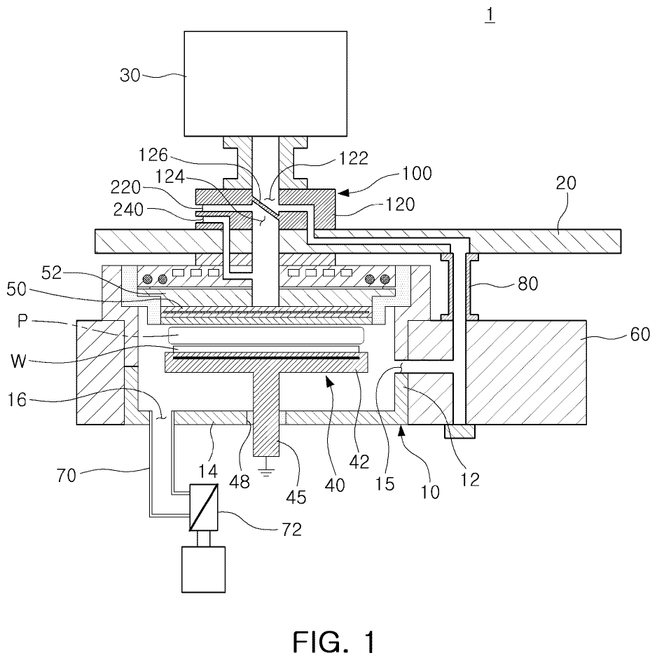

FIG. 1 is a schematic cross-sectional view of a semiconductor wafer processing apparatus according to an example embodiment of the present inventive concept.

A semiconductor wafer processing apparatus 1 according to an example of the present inventive concept may include a processing chamber 10, a remote plasma source 30, and a manifold 100.

The processing chamber 10 may be formed of a metal material such as aluminum (Al). In an example embodiment, the processing chamber 10 may include a substrate passage through which an object to be processed, such as a semiconductor wafer W (or just wafer W), is loaded or unloaded.

The processing chamber 10 may provide an internal space that is sealed from the external environment of the processing chamber 10 (which may provide a lower or higher pressure environment with respect to the external environment), and may provide a space in which a process is performed on the wafer W. The semiconductor process may include, for example, at least one of a deposition process, an etching process, or a cleaning process. Here, the etching process may include a high-aspect-ratio-contact (HARC) etching process. A HARC etching process may provide a high degree of integration of a semiconductor substrate. In addition, the deposition process may include chemical vapor deposition (CVD) and plasma enhanced chemical vapor deposition (PECVD), and may be a process of depositing an advanced patterning film on a substrate such as a semiconductor wafer W. CVD and PECVD may be performed by introducing process gases into the internal space of the processing chamber 10 in which the wafer W is located. The process gases may diffuse toward the wafer W through a showerhead 50 disposed at an upper portion of the internal space of the processing chamber 10.

While the etching process or deposition process is performed, the process gases in the processing chamber 10 may be excited into plasma by applying, to the processing chamber 10 and/or the internal space contained therein, radio frequency (RF) power from one or more RF sources coupled to the processing chamber 10.

In a process of depositing an amorphous carbon film (ACL) according to an example embodiment, deposition and cleaning may be repeatedly performed, and the remote plasma source (RPS) 30 may supply a first gas for use in processing of the wafer W. The first gas may include ions and radicals of a process gas.

The first gas may include oxygen (O) and fluorine (F) radical gases that are used to clean a carbon-deposited film material generated in a lower portion of the internal space of the processing chamber 10.

The manifold 100 may include a gas distribution flow path for distributing, to the showerhead 50 of the processing chamber 10 or a sidewall of the processing chamber 10, a process gas or a cleaning gas necessary for depositing an ACL on the wafer W in the processing chamber 10.

In addition, the semiconductor wafer processing apparatus 1 may include a gas distribution plate 52 and a wafer support 40.

The gas distribution plate 52 may be provided at the upper portion of the processing chamber 10 and may communicate with the showerhead 50. The gas distribution plate 52 may receive a process gas and/or a cleaning gas for the processing chamber 10 from a gas supply, and may distribute the process gas and/or the cleaning gas to the showerhead 50. The showerhead 50 may spray the process gas and/or cleaning gas to the wafer W in the processing chamber 10.

Due to an interaction between the showerhead 50, which supplies a process gas to the internal space of the processing chamber, and an electrostatic chuck 42 of the wafer support 40, which supports the wafer W, plasma P may be generated between the showerhead 50 and the electrostatic chuck 42.

The electrostatic chuck 42 may be an upper member of the wafer support 40 supporting the wafer W, and power, which is supplied by a power supply unit, may cause an elevation cylinder 45 to vertically rise or fall, thereby adjusting a distance between the showerhead 50 and the electrostatic chuck 42.

The electrostatic chuck 42 may be a susceptor including a heating pattern, and the heating pattern may heat the susceptor using externally supplied power. For example, the susceptor may be formed of a ceramic material such as aluminum nitride (AlN) or aluminum oxide (Al₂O₃).

A chamber lid 20 may be provided at the upper portion of the processing chamber 10. The chamber lid 20 may be provided on upper portions and/or surfaces of the showerhead 50 and/or the gas distribution plate 52 and may form a portion of a flow path for a first cleaning gas.

The first cleaning gas, which may be supplied by the remote plasma source 30, may be supplied to a sidewall 12 of the processing chamber 10 via the chamber lid 20. The first cleaning gas may be supplied to the sidewall 12 of the processing chamber 10 and may resolve a phenomenon in which a carbon film material is deposited in the internal space on a bottom portion of the processing chamber 10 or a pipe portion, causing pipe clogging.

A manifold 100 may be disposed between the chamber lid 20 of the processing chamber 10 and the remote plasma source 30. The manifold 100 provides gas distribution flow paths through which gases are supplied to the internal space of the processing chamber 10.

### Manifold

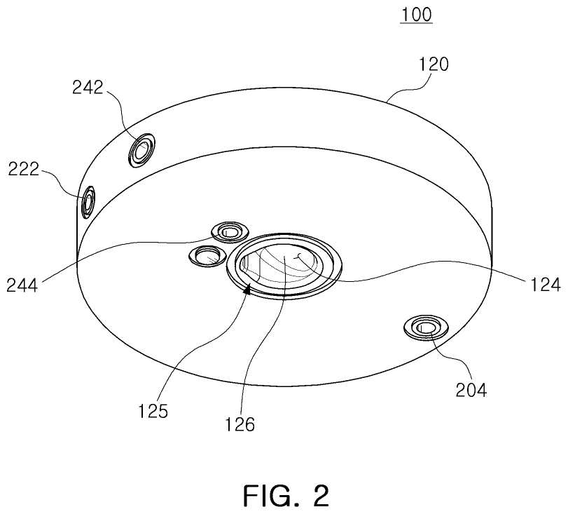

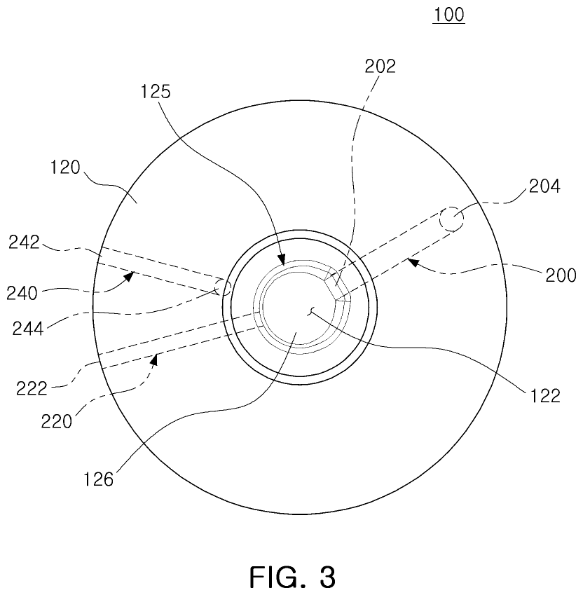

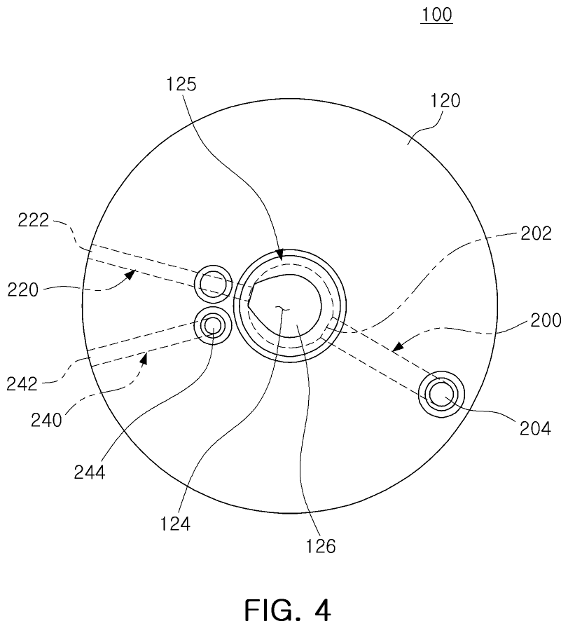

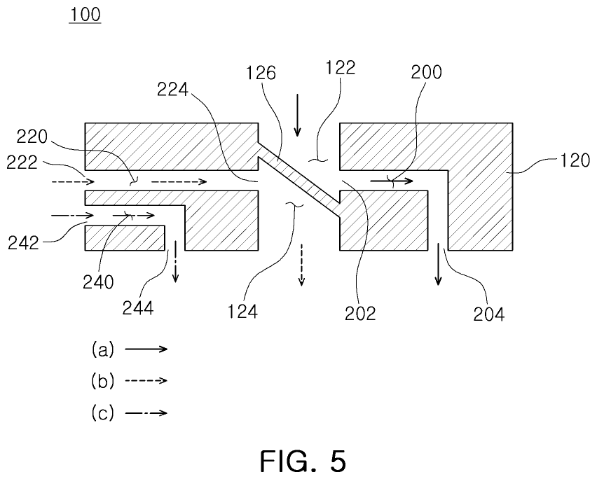

FIG. 2 is a schematic perspective view of a lower surface of a manifold suitable for use in the semiconductor wafer processing apparatus of FIG. 1. FIG. 3 is a schematic diagram of an upper surface of the manifold of FIG. 2. FIG. 4 is a schematic diagram of a lower surface of the manifold of FIG. 2. FIG. 5 is a schematic diagram of a cross-section of the manifold of FIG. 2.

Referring to FIGS. 2 to 5, the manifold 100 according to an example of the present inventive concept may include a manifold body 120, an inclined partition 126, a first gas flow path 200, a second gas flow path 220, and a third gas flow path 240.

The manifold body 120 may have a cylindrical shape. A shape of the manifold body is not particularly limited, and the manifold body 120 may have a radius greater than a thickness thereof to reduce a height thereof.

An upper hole 122 may be formed at an upper surface of the manifold body 120 though an upper portion of the manifold body 120 and a lower hole 124 may be formed a lower surface of the manifold body 120 through a lower portion of the manifold body 120. The upper portion of the manifold body may refer to a portion above the inclined partition 126 and the lower portion of the manifold body may refer to a portion below the inclined portion, taken in a thickness direction of a central portion 125 of the manifold body 120. The inclined partition 126 may partition a lower portion of the upper hole 122 and an upper portion of the lower hole 124 to separate the upper hole 122 and the lower hole 124 from each other (e.g., the upper hole 122 and the lower hole 124 may be a single passage through the manifold body 120 that is divided by the partition 126 to form the upper hole 122 and the lower hole 124).

The first gas flow path 200 may be a flow path for cleaning gases supplied by the remote plasma source 30, which may include O and F radical gases, and may communicate from the upper hole 122 above the inclined partition 126 to the outside of the manifold body 120.

An inlet 202 of the first gas flow path may be formed in a side surface of the upper hole 122 of the manifold 100, and an outlet 204 of the first gas flow path may be formed on the lower surface of the manifold body 120.

The second gas flow path 220 may start from the outside of the manifold body 120, and may communicate from a side surface of the lower hole 124 below the inclined partition 126 to the lower hole 124 of the manifold body 120.

An second gas flow path hole 222 of the second gas flow path 220 may be formed on the outside of a side surface of the manifold body 120, and may communicate with the lower hole 124, which may form an outlet of the second gas flow path 220, via one side surface of the lower hole 124.

A gas, passing through the second gas flow path, may be a nitrogen trifluoride (NF₃) cleaning gas, and may be sprayed into the interior of the processing chamber 10 through the showerhead 50.

The third gas flow path 240, which may be adjacent to the second gas flow path, may start from the outside of the side surface of the manifold body 120, and may communicate with the outside of the manifold body 120.

An inlet 242 of the third gas flow path may be formed on the outside of the side surface of the manifold body 120, and an outlet 244 of the third gas flow path may be formed on the lower portion of the manifold body 120.

A gas, passing through the third gas flow path, may be a process gas including ammonia (NF₃) and/or silicon dichloride (SiCl₂).

Referring to FIG. 5, a flow of gases, flowing through the gas distribution flow path in the manifold 100, is illustrated. Here, (a) may be the first gas flow path, (b) may be the second gas flow path, and (c) may be the third gas flow path. Although FIG. 5 illustrates all of the gases flowing at the same time, the gases may be individually controlled such that the flow of each gas through the gas distribution flow path may be independent of the flow of the other gases.

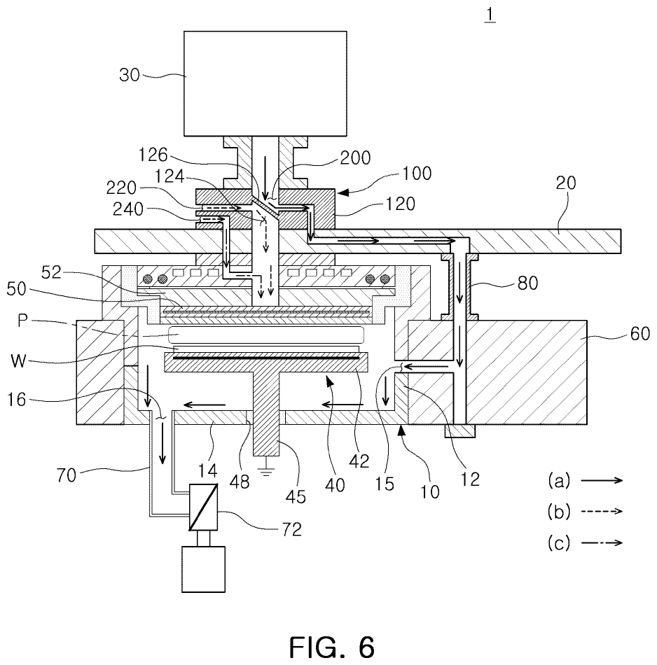

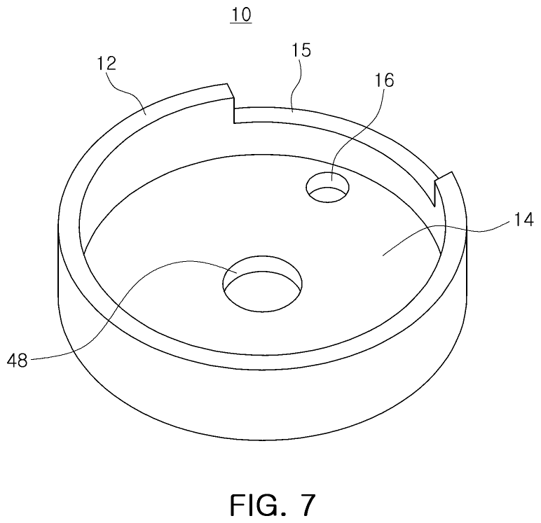

FIG. 6 is a schematic diagram of a bypass flow path through which processing gas moves in the semiconductor wafer processing apparatus of FIG. 1. FIG. 7 is a schematic perspective view of the processing chamber of FIG. 6.

With reference to FIGS. 6 and 7, a flow of gas, passing through the manifold 100 and then supplied to the processing chamber 10, will be described.

A first cleaning gas including O and F radicals may flow from the remote plasma source 30 to the upper hole 122 of the manifold 100. The first cleaning gas may then be introduced through the inlet 202 of the first gas flow path that is formed on one side surface of the upper hole 122 of the manifold 100 and discharged through the outlet 204 of the first gas flow path formed on the lower portion or lower surface of the manifold body 120.

The first cleaning gas, discharged from the outlet 204 of the first gas flow path, may communicate with an internal gas flow path of the chamber lid 20, and the internal gas flow path of the chamber lid 20 may communicate with a gas tube 80 connected to a gas flow path of a chamber wall 60 of the processing chamber 10.

The gas flow path of the chamber wall 60 may communicate with a first gas flow path hole 15 of the sidewall 12 of the processing chamber 10 which is in communication with the internal space of the processing chamber 10.

The first gas flow path hole 15 of the sidewall 12 of the processing chamber 10 may be disposed at a position lower than a position of the electrostatic chuck 42 when a plasma region P is formed in the processing chamber 10, and thus may be positioned to be close to the bottom portion of the processing chamber 10.

The first gas flow path hole 15 of the sidewall 12 of the processing chamber 10 may communicate with a discharge hole 16 for the internal space at a bottom portion 14 of the processing chamber 10 through the internal space of the processing chamber 10.

A carbon-deposited film material, formed in the internal space on the bottom portion 14 of the processing chamber 10, may react with the O and F radicals of the first cleaning gas to produce N₂, F₂, CO, CO₂, CF₄, C₂F₄, C₂F₈, etc. These products may be pumped and discharged through the discharge hole 16 at the bottom portion 14 of the processing chamber 10.

The discharge hole 16 at the bottom portion 14 of the processing chamber 10 may function as a contaminant discharge hole. The contaminant discharge hole may communicate with a foreline 70, and a lower side of the foreline 70 may be connected to a throttle valve 72 to selectively discharge contaminants. For example, the throttle valve 72 may be opened to discharge contaminants and closed to not discharge contaminants.

A gas, passing through the second gas flow path 220, may include an NF₃ cleaning gas. A second gas may be introduced through a second gas flow path hole 222, which may be called an inlet, formed in a side portion of the manifold 100, and may be discharged through the lower hole 124 of the manifold body 120.

The lower hole 124 of the manifold body may communicate with the showerhead 50 of the upper portion of the processing chamber 10 disposed below the manifold 100, and the second gas may be sprayed into the internal space of the processing chamber 10 through the showerhead 50.

A process gas, passing through the third gas flow path 240, may include NH₃ and SiCl₂. The third gas flow path 240, adjacent to the second gas flow path 220, may start from the outside of the side surface of the manifold body 120, and may communicate with the outside of the manifold body 120.

An inlet 242 of the third gas flow path may be formed on the outside of the side surface of the manifold body 120, and an outlet 244 of the third gas flow path may be formed on the lower portion or lower surface of the manifold body 120.

The outlet 244 of the third gas flow path of the lower portion of the manifold body 120 may communicate with the showerhead 50 of the upper portion of the processing chamber 10, and the third gas may be sprayed into the internal space of the processing chamber 10 through the showerhead 50.

A process gas and a cleaning gas may be appropriately supplied to perform a process of depositing an ACL on the wafer W in the internal space of the processing chamber 10. When depositing the ACL on the wafer W a carbon film material, deposited in the internal space on the lower portion of the processing chamber 10, may react with the O and F radicals of the first cleaning gas, such that contaminants may discharged from the internal space through the discharge hole 16 at the bottom portion 14 of the processing chamber 10.

According to a manifold and a semiconductor wafer processing apparatus of the present inventive concept, a bypass plasma cleaning gas flow path may be provided to directly remove a carbon film material collected on a lower portion of a processing chamber, thereby preventing the carbon film material from being accumulated on the lower portion of the processing chamber, a vacuum pipe, and a throttle valve portion to resolve an issue such as process stopping or pipe clogging.

While example embodiments have been shown and described above, it will be apparent to those skilled in the art that modifications and variations could be made without departing from the scope of the present inventive concept.

What is claimed is:

1. A manifold comprising:
a manifold body having an upper surface, a lower surface, at least one side surface between the upper surface and the lower surface, an upper hole in the upper surface, a lower hole in the lower surface, a first inlet, a second inlet, a first outlet, and a second outlet;
an inclined partition separating the upper hole and the lower hole from each other in a thickness direction of a central portion of the manifold body;
a first gas flow path providing fluid communication between the upper hole above the inclined partition and the first outlet of the manifold body;
a second gas flow path providing fluid communication between the first inlet and a side surface of the lower hole below the inclined partition and continuing to the lower hole of the manifold body; and
a third gas flow path providing fluid communication between the second inlet and the second outlet of the manifold body.

2. The manifold of claim 1, further comprising an oxygen (O) and fluorine (F) radical gas source in communication with the first gas flow path, and
the first outlet is formed on the lower surface of the manifold body.

3. The manifold of claim 1, further comprising a nitrogen trifluoride (NF3) gas source in communication with the second gas flow path.

4. The manifold of claim 1, further comprising an ammonia (NH3) gas source and a silicon dichloride (SiCL2) gas source each in communication with the third gas flow path, wherein
the second outlet is formed on the lower surface of the manifold body.

5. A semiconductor wafer processing apparatus comprising:
a processing chamber having a chamber lid at an upper portion thereof and an internal space;
a remote plasma source disposed at an upper portion of the chamber lid, the remote plasma source supplying a plasma cleaning gas to the internal space of the processing chamber; and
a manifold disposed between the remote plasma source and the chamber lid, the manifold providing gas distribution flow paths to the processing chamber,
wherein the gas distribution flow paths of the manifold provide a first cleaning gas, supplied by the remote plasma source, to the internal space of the processing chamber through a sidewall of the processing chamber via the chamber lid.

6. The semiconductor wafer processing apparatus of claim 5, wherein the manifold includes:
a manifold body having an upper surface, a lower surface, at least one side surface between the upper surface and the lower surface, an upper hole in the upper surface, a lower hole in the lower surface, a first inlet, a second inlet, a first outlet, and a second outlet;
an inclined partition separating the upper hole and the lower hole from each other in a thickness direction of a central portion of the manifold body;
a first gas flow path providing fluid communication between the upper hole above the inclined partition to the first outlet of the manifold body;
a second gas flow path providing fluid communication between the first inlet to a side surface of the lower hole below the inclined partition and continuing to the lower hole of the manifold body; and
a third gas flow path providing fluid communication between the second inlet to the second outlet of the manifold body.

7. The semiconductor wafer processing apparatus of claim 6, further comprising an (oxygen) O and fluorine (F) radical gas source in communication with the first gas flow path, wherein the first outlet is formed on the lower surface of the manifold body.

8. The semiconductor wafer processing apparatus of claim 7, wherein
the first outlet communicates with an internal gas flow path of the chamber lid,
the internal gas flow path of the chamber lid communicates with a gas tube connected to a gas flow path of a chamber wall of the processing chamber, and
the gas flow path of the chamber wall communicates with the internal space through a first gas flow path hole of the sidewall of the processing chamber.

9. The semiconductor wafer processing apparatus of claim 8, further comprising an electrostatic chuck, wherein the first gas flow path hole of the sidewall of the processing chamber is disposed at a position lower than a position of the electrostatic chuck when a plasma region is formed in the internal space of the processing chamber.

10. The semiconductor wafer processing apparatus of claim 8, wherein the first gas flow path hole of the sidewall of the processing chamber communicates with a discharge hole at a bottom portion of the processing chamber.

11. The semiconductor wafer processing apparatus of claim 6, further comprising a nitrogen trifluoride (NF₃) gas source in communication with the second gas flow path.

12. The semiconductor wafer processing apparatus of claim 11, wherein
the lower hole of the manifold body communicates with a showerhead of an upper portion of the processing chamber and that is disposed below the manifold, and
the second gas is sprayed into the internal space of the processing chamber through the showerhead.

13. The semiconductor wafer processing apparatus of claim 6, further comprising an ammonia (NH₃) gas source and a silicon dichloride (SiCL₂) gas source each in communication with the third gas flow path, wherein
the second outlet is formed at the lower surface of the manifold body.

14. The semiconductor wafer processing apparatus of claim 13, wherein
the second outlet communicates with a showerhead at an upper portion of the processing chamber, and
the second gas is sprayed into the internal space of the processing chamber through the showerhead.

15. The semiconductor wafer processing apparatus of claim 6, wherein
a contaminant discharge hole is formed in a lower surface of the processing chamber,
the contaminant discharge hole communicates with a foreline, and
a lower side of the foreline is connected to a throttle valve and selectively discharges contaminants.

16. A semiconductor wafer processing apparatus comprising:
a processing chamber having a chamber lid at an upper portion thereof and an internal space;
a manifold on the chamber lid, the manifold providing gas distribution flow paths to the processing chamber; and
a remote plasma source supplying a plasma cleaning gas to the internal space of the processing chamber through the manifold; and
wherein the manifold includes:
a manifold body having an upper surface, a lower surface, at least one side surface between the upper surface and the lower surface, an upper hole in the upper surface, a lower hole in the lower surface, a first inlet, a second inlet, a first outlet, and a second outlet;
an inclined partition separating the upper hole and the lower hole from each other in a thickness direction of a central portion of the manifold body;
a first gas flow path providing fluid communication between the upper hole above the inclined partition to the first outlet of the manifold body;
a second gas flow path providing fluid communication between the first inlet to a side surface of the lower hole below the inclined partition and continuing to the lower hole of the manifold body; and
a third gas flow path providing fluid communication between the second inlet to the second outlet of the manifold body.

17. The semiconductor wafer processing apparatus of claim 16, further comprising an electrostatic chuck, wherein
the remote plasma source is an oxygen (O) radical gas source and a fluorine (F) radical gas source, and
the first gas flow path is formed such that the plasma cleaning gas, supplied by the remote plasma source, is supplied to a sidewall of the processing chamber via the chamber lid,
the first outlet of the first gas flow path is formed at the lower surface of the manifold body, and communicates with an internal gas flow path of the chamber lid,
the internal gas flow path of the chamber lid communicates with a gas tube connected to a gas flow path of a chamber wall of the processing chamber,
the gas flow path of the chamber wall communicates with the internal space through a first gas flow path hole of the sidewall of the processing chamber, and
the first gas flow path hole of the sidewall of the processing chamber is disposed at a position lower than a position of the electrostatic chuck when a plasma region is formed in the processing chamber.

18. The semiconductor wafer processing apparatus of claim 16, further comprising a nitrogen trifluoride (NF3) gas source in communication with the second gas flow path, wherein
the lower hole of the manifold body communicates with a showerhead of an upper portion of the processing chamber and that is disposed below the manifold, and
the second gas is sprayed into the internal space of the processing chamber through the showerhead.

19. The semiconductor wafer processing apparatus of claim 16, further comprising an ammonia (NH3) gas source and a silicon dichloride (SiCL2) gas source each in communication with the third gas flow path, wherein
the second outlet is formed at the lower surface of the manifold body,
the second outlet communicates with a showerhead of an upper portion of the processing chamber, and
a gas is sprayed into the processing chamber through the showerhead.

20. The semiconductor wafer processing apparatus of claim 16, wherein
a contaminant discharge hole is formed in a lower surface of the processing chamber,
the contaminant discharge hole communicates with a foreline, and
a lower side of the foreline is connected to a throttle valve and selectively discharges contaminants.
